(19) United States
(12) Patent Application Publication
(10) Pub. No.: US 2020/0140058 A1
(43) Pub. Date: May 7, 2020

(54) ELECTRONIC SPEED CONTROLLER ASSEMBLY, POWER SYSTEM, AND UNMANNED AERIAL VEHICLE

(71) Applicant: SZ DJI TECHNOLOGY CO., LTD., Shenzhen (CN)

(72) Inventors: Guibin LIANG, Shenzhen (CN); Yucheng LIU, Shenzhen (CN)

(21) Appl. No.: 16/726,690

(22) Filed: Dec. 24, 2019

Related U.S. Application Data
(63) Continuation of application No. PCT/CN2017/099962, filed on Aug. 31, 2017.

(51) Int. Cl. B64C 1/38; B64C 39/02; H05K 7/20

(52) U.S. Cl. CPC B64C 1/38; B64C 2201/14; H05K 7/20409; B64C 39/024

(57) ABSTRACT

An electronic speed controller (ESC) assembly for an unmanned aerial vehicle includes a first ESC for driving a first motor, a second ESC for driving a second motor, and a heat sink assembly disposed between the first ESC and the second ESC. The first motor is configured to drive an upper propeller to generate a lift, and the second motor is configured to drive a lower propeller to generate a lift. The first ESC and the second ESC are alternately disposed. The heat sink assembly includes a heat sink main body, and a thermally conductive metal and a heat dissipation pipe disposed on the heat sink main body. The thermally conductive metal is connected to the heat dissipation pipe. The first ESC and the second ESC are respectively in contact with the thermally conductive metal on the heat sink main body to transfer generated heat to the thermally conductive metal.

### CROSS-REFERENCE TO RELATED APPLICATION

This application is a continuation of International Application No. PCT/CN2017/099962, filed Aug. 31, 2017, the entire content of which is incorporated herein by reference.

### TECHNICAL FIELD

The present disclosure relates to the field of unmanned aerial vehicle technology and, more particularly, to an electronic speed controller assembly, a power system and an unmanned aerial vehicle thereof.

### BACKGROUND

With the rapid development of science and technology, unmanned aerial vehicle (UAV) technology is becoming more and more mature, and more and more types of UAVs are developed. According to the number of rotors, the UAVs may be classified as single-rotor UAVs and multi-rotor UAVs. For multi-rotor UAVs, the power system generally includes a motor, a propeller, and an electronic speed controller (ESC), etc. The ESC is used to drive the motor to cause the change of the rotational speed of the motor. The motor drives the propeller to generate a lift, so as to provide flight propulsion for the multi-rotor UAVs. It should be noted that, during the flight of multi-rotor UAVs, the ESC will generate a large amount of heat. If there is no effective approach to dissipate heat, the efficiency of the ESC will drop or even some important components of a UAV are damaged, which may sequentially cause a UAV to lose propulsion, or have other serious consequences, e.g., even crush. Therefore, when designing a UAV, it is necessary to develop an excellent heat dissipation approach for its ESC.

At present, the power systems of the existing multi-rotor UAVs may be classified as single-axis single-blade systems and coaxial twin-blade systems. Single-axis single-blade systems are generally more efficient than coaxial twin-blade systems. However, within a certain projected area, the coaxial twin-blade systems provide much more lift for the UAVs than the single-axis single-blade systems. Regarding the design of ESC heat dissipation, in the current market, there are ESC heat sinks corresponding to the single-axis single-blade systems, but no ESC heat sink for the coaxial twin-blade systems. If the ESC heat sinks corresponding to the single-axis single-blade systems are installed on the coaxial twin-blade systems, there will be many disadvantages in the design and installation of such ESCs, e.g., poor heat dissipation, inconvenient for maintenance, and excessive size, etc.

### SUMMARY

In accordance with the present disclosure, there is provided an ESC assembly for a UAV. The ESC assembly includes a first ESC for driving a first motor, a second ESC for driving a second motor, and a heat sink assembly disposed between the first ESC and the second ESC. The first motor is configured to drive an upper propeller to generate a lift, and the second motor is configured to drive a lower propeller to generate a lift. The first ESC and the second ESC are alternately disposed. The heat sink assembly includes a heat sink main body, and a thermally conductive metal and a heat dissipation pipe disposed on the heat sink main body, where the thermally conductive metal is connected to the heat dissipation pipe, and the first ESC and the second ESC are respectively in contact with the thermally conductive metal on the heat sink main body to transfer generated heat to the thermally conductive metal.

Also in accordance with the disclosure, there is provided a power system for a UAV. The power system includes a propeller, a first motor, a second motor, and an ESC assembly for driving the first motor and the second motor. The propeller includes an upper propeller connected with the first motor and a lower propeller connected with the second motor. The ESC assembly includes a first ESC for driving the first motor, a second ESC for driving the second motor, and a heat sink assembly disposed between the first ESC and the second ESC. The first motor is configured to drive the upper propeller to generate a lift, and the second motor is configured to drive the lower propeller to generate a lift. The first ESC and the second ESC are alternately disposed. The heat sink assembly includes a heat sink main body, and a thermally conductive metal and a heat dissipation pipe disposed on the heat sink main body, where the thermally conductive metal is connected to the heat dissipation pipe, and the first ESC and the second ESC are respectively in contact with the thermally conductive metal on the heat sink main body to transfer generated heat to the thermally conductive metal.

Also in accordance with the disclosure, there is provided a UAV. The UAV includes a central body, an arm connected to the central body, and a power system disposed at or near an end of the arm. The power system may be a power system described above.

### BRIEF DESCRIPTION OF THE DRAWINGS

FIG. 1 is a schematic structural diagram of an ESC assembly according to some embodiments of the present disclosure;

FIG. 2 is a schematic structural diagram of an ESC assembly according to other embodiments of the present disclosure;

FIG. 3 is a schematic structural diagram of a heat dissipation pipe according to some embodiments of the present disclosure;

FIG. 4 is a schematic structural diagram of an assembled power system according to some embodiments of the present disclosure;

FIG. 5 is a schematic structural diagram of a split power system according to some embodiments of the present disclosure;

FIG. 6 is a schematic structural diagram of a part of a power system according to some embodiments of the present disclosure; and

FIG. 7 is a schematic structural diagram of a part of a power system according to other embodiments of the present disclosure.

### DETAILED DESCRIPTION OF THE EMBODIMENTS

To make the objective, technical solutions, and advantages of the present disclosure clearer, the technical solutions of the present disclosure will be made in detail hereinafter with reference to the accompanying drawings. Apparently, the described embodiments are merely some, but not all, of the embodiments of the present disclosure. Various other embodiments obtained by a person of ordinary skill in the art based on the embodiments of the present disclosure without creative efforts still fall within the protection scope of the present disclosure.

Unless otherwise specified, all the technical and scientific terms used herein have the same or similar meaning as generally known to those with ordinary skills in the art. As described herein, the terms used in the description of the present disclosure are merely for the purpose of describing specific embodiments, but are not intended to limit the disclosure. The term “and/or” used herein includes any suitable combinations of one or more of the associated listed items.

In the present disclosure, the terms “installation”, “connection”, “fixation” and the like are to be interpreted in their broadest meanings. For example, “connection” may be a fixed connection, a detachable connection, or an integral connection. For those skilled in the art, the specific meanings of the above terms in the present disclosure may be interpreted on a case-by-case basis.

In the descriptions of the present disclosure, it is to be understood that the orientations and position relationships defined by the terms “center”, “longitudinal”, “transverse”, “length”, “width”, “thickness”, “upper”, “lower”, “front”, “back”, “left”, “right”, “vertical”, “horizontal”, “top”, “bottom”, “inside”, “outside”, etc., are based on the orientations and position relationships shown in the drawing, which are merely for the purpose of facilitating the description of the disclosure, but do not explicitly and inherently require that the defined components or units to have the exact orientations or positions to be organized or to operate, and thus should not be constructed as a limitation of the present disclosure.

Embodiments of the present disclosure will be made in detail hereinafter with reference to the accompanying drawings. The characteristics of the embodiments and examples described hereinafter may be combined with each other as desired if no conflict exists.

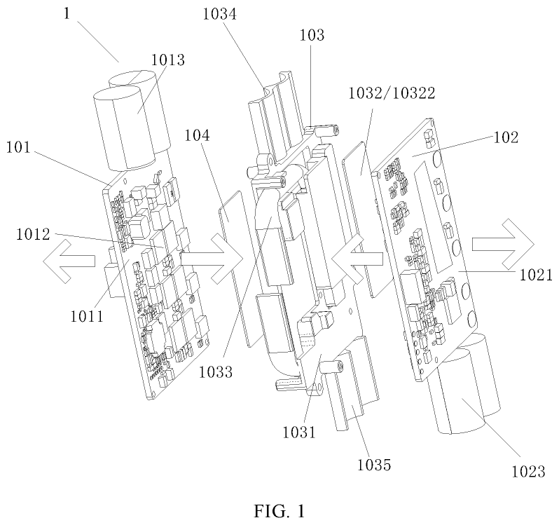

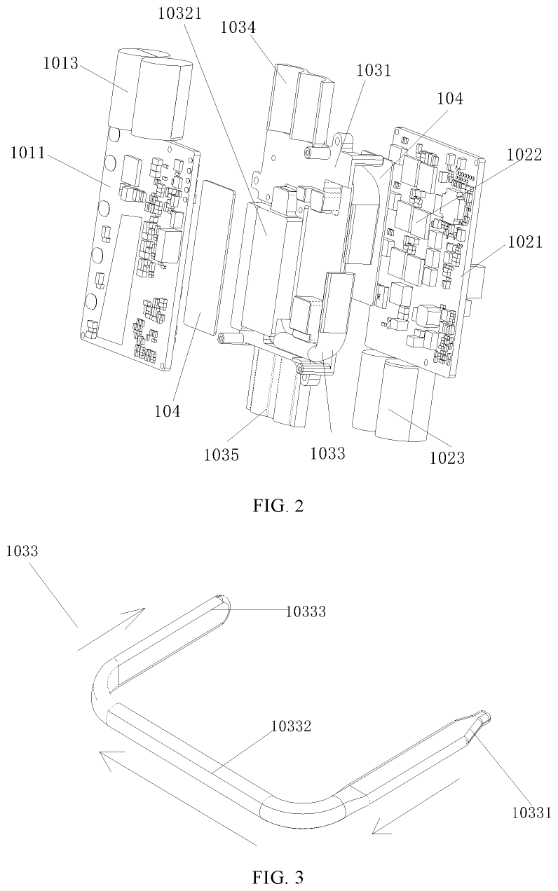

FIG. 1 is a schematic structural diagram of an ESC assembly according to some embodiments of the present disclosure. FIG. 2 is a schematic structural diagram of an ESC assembly according to other embodiments of the present disclosure. Referring to FIGS. 1 and 2, embodiments of the present disclosure provide an ESC assembly 1 that has good heat dissipation performance and is convenient for maintenance. Specifically, the ESC assembly 1 may include: a first ESC 101 for driving a first motor, a second ESC 102 for driving a second motor, and a heat sink assembly 103 disposed between the first ESC 101 and the second ESC 102. The first motor is configured to drive an upper propeller to generate a lift, and the second motor is configured to drive a lower propeller to generate a lift. The first ESC 101 and the second ESC 102 are alternately disposed. The heat sink assembly 103 includes a heat sink main body 1031, and a thermally conductive metal 1032 and a heat dissipation pipe 1033 disposed on the heat sink main body 1031. The thermally conductive metal 1032 is connected with the heat dissipation pipe 1033. The first ESC 101 and the second ESC 102 are respectively in contact with the thermally conductive metal 1032 on the heat sink main body 1031 to transfer the generated heat to the thermally conductive metal 1032.

In the disclosed embodiments, the ESC assembly 1 includes a first ESC 101 and a second ESC 102. The first ESC 101 is used to drive a first motor, and the second ESC 102 is used to drive a second motor. Specifically, the first ESC 101 may be connected to the first motor through a wire, the second ESC 102 may be connected to the second motor through a wire. The first ESC 101 and the second ESC 102 may be respectively connected with a flight controller to receive a control signal sent by the flight controller, so as to drive the first motor and the second motor, respectively. In specific operations, the first ESC 101 and the second ESC 102 may generate a large amount of heat. In order to achieve good heat dissipation performance for the first ESC 101 and the second ESC 102, the first ESC 101 and the second ESC 102 may be alternately disposed on the left and right sides of the heat sink assembly 103. Assume that the first ESC 101 is disposed on the left side of the heat sink assembly 103 and the second ESC 102 is disposed on the right side of the heat sink assembly 103. At this moment, part of the heat from the first ESC 101 is dissipated to the left side, while most of the heat is transferred to the heat sink assembly 103 on the right side and is dissipated through the heat sink assembly 103. Similarly, part of the heat from the second ESC 102 is dissipated to the right side, while most of the heat is transferred to the heat sink assembly 103 on the left side and is dissipated through the heat sink assembly 103. In this way, the heat from both the first ESC 101 and the second ESC 102 may be effectively dissipated through the heat sink assembly 103. Accordingly, the stability and reliability for the operation of the ESC assembly 1 may be ensured.

Further, the disclosed embodiments do not limit the specific way for alternately disposing the first ESC 101 and the second ESC 102, and those skilled in the art may set/select/determine according to specific design requirements. In one example, the first ESC 101 and the second ESC 102 may be alternately disposed and form an oblique angle, which may be an acute angle, a right angle or an obtuse angle. Here, in order to reduce the space occupied by the ESC assembly 1, it is desirable that the first ESC 101 and the second ESC 102 of the ESC assembly 1 are alternately disposed and form an angle of 180°. That is, the front end of the first ESC 101 is opposite to the back end of the second ESC 102, while the back end of the first ESC 101 is opposite to the front end of the second ESC 102.

In a specific application, when the ESC assembly 1 is in operation, that is, after receiving the control signal from the flight controller, the first ESC 101 may drive the first motor to run, thereby driving the upper propeller to generate a lift, and the second ESC may drive the second motor to run, thereby driving the lower propeller to generate a lift. At this moment, both the first ESC 101 and the second ESC 102 may generate a large amount of heat. However, due to the heat sink assembly 103 disposed between the first ESC 101 and the second ESC 102, the generated heat may be quickly dissipated through the heat sink assembly 103. Specifically, most of the heat generated by the first ESC 101 is quickly transferred, through the thermally conductive metal 1032, to the heat dissipation pipe 1033. At this moment, through the heat dissipation pipe 1033 of the heat sink assembly 103, the generated heat may be quickly dissipated. Similarly, most of the heat generated by the second ESC 102 is also transferred, through the thermally conductive metal 1032, to the heat dissipation pipe 1033. Through the heat dissipation pipe 1033 of the heat sink assembly 103, the generated heat may be also quickly dissipated. In this way, quick and effective heat dissipation may be achieved for the first ESC 101 and the second ESC 102, thereby improving the stability and reliability of operation of the first ESC 101 and the second ESC 102.

For the ESC assembly 1 provided in the disclosed embodiments, through alternately disposing the first ESC 101 and the second ESC 102, the space occupied by the ESC assembly 1 may be effectively reduced. Meanwhile, when both the first ESC 101 and the second ESC 102 generate a large amount of heat, the heat sink assembly 103 disposed between the first ESC 101 and the second ESC 102 may be used to effectively dissipate heat generated by the first ESC 101 and the second ESC 102. Specifically, through the thermally conductive metal 1032 on the heat sink assembly 103, most of the heat generated by the ESCs may be quickly transferred to the heat dissipation pipe 1033, then the heat dissipation pipe 1033 may quickly dissipate the generated heat. Accordingly, the heat generated by the first ESC 101 and the second ESC 102 may be quickly and effectively dissipated, thereby improving the stability and reliability of the ESC assembly 1 and facilitating the maintenance of the ESC assembly 1. This ensures practical applications of the ESC assembly 1, thereby facilitating its market promotions and applications.

In view of the foregoing embodiments, continuing to refer to FIGS. 1 and 2, it can be seen that the first ESC 101 and the second ESC 102 are respectively disposed on the left and right sides of the heat sink assembly 103, and the first ESC 101 and the second ESC 102 are respectively connected to the heat dissipation pipe 1033 through the thermally conductive metal 1032. Accordingly, in order to ensure the heat dissipation performance of the first ESC 101 and the second ESC 102, the thermally conductive metal 1032 in the disclosed embodiments may include a first thermally conductive metal 10321 disposed on one side of the heat sink assembly 103. The first ESC 101 is brought into contact with the first thermally conductive metal 10321.

The specific shape and structure of the first thermally conductive metal 10321 are not limited, and those skilled in the art may set/select/determine according to specific design requirements. In one example, the first thermally conductive metal 10321 may be a rectangular structure, a square structure, a circular structure, an elliptical structure or other irregular structures, etc. The first thermally conductive metal 10321 may be made of a material like silver, copper, aluminum, alloy or any other materials, as long as a high thermal conductivity is ensured for the first thermally conductive metal 10321. In addition, when the first ESC 101 transfers heat to the heat dissipation pipe 1033 through the first thermally conductive metal 10321, in order to ensure the stability and reliability of heat transfer, the first ESC 101 may be brought into contact with the first thermally conductive metal 10321 through a thermally conductive silicone 104. That is, the first ESC 101 adheres to the thermally conductive silicone 104, and the thermally conductive silicone 104 adheres to the first thermally conductive metal 10321. In this way, most of the heat generated by the first ESC 101 may be effectively transferred to the first thermally conductive metal 10321 through the thermally conductive silicone 104.

Similarly, the thermally conductive metal 1032 may further include a second thermally conductive metal 10322 disposed on the other side of the heat sink assembly 103, and the second ESC 102 is brought into contact with the second thermally conductive metal 10322. Specifically, the second ESC 102 is in contact with the second thermally conductive metal 10322 through the thermally conductive silicone 104.

Here, the specific shape and structure of the second thermally conductive metal 10322 and the heat dissipation principle of the second thermally conductive metal 10322 for the second ESC 102 are the same as the shape and structure of the first thermally conductive metal 10321 and the heat dissipation principle of the first thermally conductive metal 10321 for the first ESC 101. For specific details, refer to the foregoing descriptions, which will not be repeated again here.

In the disclosed embodiments, by organizing the thermally conductive metal 1032 in the heat sink assembly 103 as the first thermally conductive metal 10321 and the second thermally conductive metal 10322, the heat dissipation performance of the heat sink assembly 103 for the first ESC 101 and the second ESC 102 is effectively improved. This further ensures the quality and efficiency of heat dissipation of the ESC assembly 1, and thus improves the stability and reliability of the ESC assembly 1.

FIG. 3 is a schematic structural diagram of a heat dissipation pipe according to some embodiments of the present disclosure. In view of the foregoing embodiments, continuing to refer to FIGS. 1-3, the disclosed embodiments do not limit the number, shape and structure of the disposed heat dissipation pipe 1033 of the heat sink assembly 103, and those skilled in the art may set/select/determine according to specific design requirements. With respect to the number of heat dissipation pipes 1033, it is desirable that the number of heat dissipation pipes 1033 is at least two. For instance, the number of heat dissipation pipes 1033 may be set to two, three, four or five, etc. The plurality of heat dissipation pipes 1033 may be evenly distributed in the heat sink assembly 103. When the number of heat dissipation pipes 1033 is two, for easier implementation, the two heat dissipation pipes 1033 may be oppositely disposed in the heat sink assembly 103: the first ESC 101 is connected to one of the two heat dissipation pipes 1033 through the first thermally conductive metal 10321, and the second ESC 102 is connected to the other heat dissipation pipe 1033 through the second thermally conductive metal 10322.

Further, regarding the specific shape and structure, the heat dissipation pipes 1033 may be a ring-shaped structure, a column-shaped structure, a U-shaped structure, an m-shaped structure, or the like, as long as the effective heat dissipation performance is ensured for the heat dissipation pipes 1033. For instance, as shown in FIG. 3, a heat dissipation pipe 1033 may have a U-shaped structure. Specifically, the heat dissipation pipe 1033 may include a heat receiving end 10331, a pipe body 10332, and a heat dissipating end 10333. The heat receiving end 10331 connects to the heat dissipating end 10333 through the pipe body 10332. In order to ensure the heat dissipation performance of a heat dissipation pipe 1033, the heat receiving end 10331 of the heat dissipation pipe 1033 is connected to the thermally conductive metal 1032, and the heat dissipating end 10333 may be connected to metal fins. The metal fins may be disposed on the motor mount, which is configured to mount the first motor and the second motor. When disposing the metal fins on the motor mount, multiple metal fins may be disposed, and these metal fins may be evenly spread across the outer surface of the motor mount.

In a specific application, liquid may be put inside the pipe body 10332 of a heat dissipation pipe 1033. The liquid may be silicone grease or water, etc. The liquid may quickly transfer heat received by the heat receiving end 10331. In addition, in order to facilitate the distinction between the heat receiving end 10331 and the heat dissipating end 10333 of a heat dissipation pipe 1033 to ensure the correct and reliable connection between the thermally conductive metal 1032 and the heat dissipation pipe 1033, the heat receiving end 10331 and the heat dissipating end 10333 may be configured to have different shapes. For example, the heat receiving end 10331 may be configured to have a round end while the heat dissipating end 10333 is configured to have a sharp end. Alternatively, as shown in FIG. 3, the heat receiving end 10331 may be configured to have a sharp end while the heat dissipating end 10333 is configured to have a round end. The specific examples will not be further provided here, as long as they allow a user to easily distinguish a heat receiving end 10331 from a heat dissipating end 10333.

In some embodiments, a plurality of heat dissipation pipes 1033 may be configured. Each of the plurality of heat dissipation pipes 1033 may include a heat receiving end 10331 and a heat dissipating end 10333, so that the heat generated by an ESC is transferred to the heat receiving ends 10331 of the plurality of heat dissipation pipes 1033 through the thermally conductive metal 1032. After receiving the generated heat, the heat receiving ends 10331 may quickly transfer the heat, through the pipe bodies 10332, to the heat dissipating ends 10333 for heat dissipation. Further, since the heat dissipating ends 10333 are also connected with metal fins, the heat generated by the ESC is dissipated even more quickly, thereby effectively improving the heat dissipation performance of the ESC assembly 1.

In view of the foregoing embodiments, continuing to refer to FIGS. 1-3, the disclosed embodiments do not limit the specific shape and structure of the first ESC 101 and the second ESC 102, and those skilled in the art may set/select/determine according to specific design requirements. In one example, the first ESC 101 includes a first motherboard 1011 and a first main heat irradiating component 1012 disposed on the first motherboard 1011. The first main heat irradiating component 1012 may be in contact with the first thermally conductive metal 10321 through the thermally conductive silicone 104.

The first motherboard 1011 may be a main circuit board of the first ESC 101. The main circuit board may be loaded with a plurality of electrical components. The first main heat irradiating component 1012 may be an electric component, among the plurality of electric components, that generates the most heat. The first main heat irradiating component 1012 may be disposed at any position on the first motherboard 1011. When the areas of the thermally conductive silicone 104 and the first thermally conductive metal 10321 are not large, the positions of the thermally conductive silicone 104 and the first thermally conductive metal 10321 may be set to be aligned with the position in which the first main heat irradiating component 1012 is disposed. This may bring the first main heat irradiating component 1012 into close contact with the first thermally conductive metal 10321 through the thermally conductive silicone 104.

In addition, in the disclosed embodiments, there may be one or more first main heat irradiating components 1012 disposed on the first motherboard 1011. When there is only one first main heat irradiating component 1012, the number of the first thermally conductive metal 10321 and the thermally conductive silicone 104 may also be one. At this moment, the positions of the thermally conductive silicone 104 and the first thermally conductive metal 10321 may be set to align with the position of the first main heat irradiating component 1012. The surface areas of the thermally conductive silicone 104 and the first thermally conductive metal 10321 may be set to match the surface area of the first main heat irradiating component 1012. When there are multiple first main heat irradiating components 1012, the multiple first main heat irradiating components 1012 may be distributed at different locations on the first motherboard 1011. At this moment, for the first thermally conductive metal 10321 and the thermally conductive silicone 104, in some embodiments, the areas of the thermally conductive silicone 104 and the first thermally conductive metal 10321 may be quite large, and thus one thermally conductive silicone 104 and one first thermally conductive metal 10321 may be enough for being brought into contact with the multiple first main heat irradiating components 1012. In some embodiments, the areas of the thermally conductive silicone 104 and the first thermally conductive metal 10321 may be small. At this point, multiple thermally conductive silicones 104 and multiple first thermally conductive metals 10321 may be brought into contact with the multiple first main heat irradiating components 1012. That is, each of the first main heat irradiating components 1012 may be in contact with one first thermally conductive metal 10321 through a respective thermally conductive silicone 104. In this way, the heat generated by a first main heat irradiating component 1012 may be effectively dissipated via the adjacent first thermally conductive metal 10321, thereby ensuring the stability and reliability of the first ESC 101. It is to be understood that, in some embodiments, there may be two, three, or another number of first main heat irradiating components 1012 that are brought into contact with one first thermally conductive metal 10321 through one respective thermally conductive silicone 104. The possible number of multiple first main heat irradiating components in contact with one first thermally conductive metal is not specified here, as long as the stability and reliability are ensured for the contact of the first main heat irradiating components 1012 with the first thermally conductive metal 10321 through the respective thermally conductive silicone 104.

Regarding various approaches to dissipating heat for the first ESC 101, besides the above-described approach to dissipate the heat generated by the first main heat irradiating component 1012 through the first thermally conductive metal 10321, part of the heat generated by the first main heat irradiating component 1012 may be dissipated through other electronic components. Accordingly, in the disclosed embodiments, the first ESC 101 may further include a first capacitor 1013 disposed at one end of the first motherboard 1011. A first recess 1034 for holding the first capacitor 1013 may be configured on the heat sink main body 1031.

In particular, the exact shape and structure of the first capacitor 1013 are not limited in the disclosed embodiments, and those skilled in the art may set/select/determine according to specific design requirements. In one example, the first capacitor 1013 may have a cylindrical structure. Since the first capacitor 1013 needs to fit in the first recess 1034, the shape and structure of the first recess 1034 may need to match the shape and structure of the first capacitor 1013. Accordingly, the first recess 1034 may be a semi-circular or an arc structure. In addition, the first capacitor 1013 is connected with the first motherboard 1011. Accordingly, part of the heat generated on the first motherboard 1011 may also be transferred to the first capacitor 1013. Since the first capacitor 1013 is located at an end of the motherboard 1011, the heat may be dissipated into the air through the first capacitor 1013, thereby further improving the heat dissipation performance of the first ESC 101.

Further, for the second ESC 102, it may include a second motherboard 1021 and a second main heat irradiating component 1022 disposed on the second motherboard 1021. The second main heat irradiating component 1022 may be in contact with the second thermally conductive metal 10322 through the thermally conductive silicone 104.

The second ESC 102 may further include a second capacitor 1023 disposed at one end of the second motherboard 1021. The heat sink main body 1031 is provided with a second recess 1035 for holding the second capacitor 1023. Since the first ESC 101 and the second ESC 102 are alternately disposed, the first recess 1034 may be placed at an upper part of the heat sink main body 1031, while the second recess 1035 is placed at a lower part of the heat sink main body 1031.

In the disclosed embodiments, the structure of the second motherboard 1021 of the second ESC 102, and the structure, the heat dissipation principle and the heat dissipation performance of the second main heat irradiating component 1022 may be the same as the structure of the first motherboard 1011 of the first ESC 101, and the structure, the heat dissipation principle and the heat dissipation performance of the first main heat irradiating component 1012, details of which may refer to the foregoing descriptions and will not be repeated again here. In addition, the functions of the second capacitor 1023 in the disclosed embodiments may be the same as the functions of the first capacitor 1013 in the foregoing embodiments, details of which may refer to the foregoing descriptions and will not be repeated again here, either.

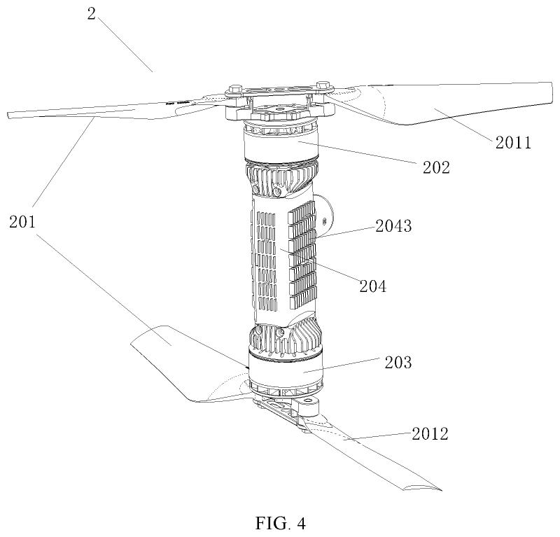

FIG. 4 is a schematic structural diagram of an assembled power system according to some embodiments of the present disclosure. Referring to FIG. 4, in another aspect, the disclosed embodiments provide a power system 2. The power system 2 includes propellers 201, a first motor 202, a second motor 203 and the ESC assembly for driving the first motor 202 and the second motor 203. The propellers 201 includes an upper propeller 2011 connected to the first motor 202 and a lower propeller 2012 connected to the second motor 203.

The ESC assembly includes a first ESC for driving the first motor 202, a second ESC for driving the second motor 203, and a heat sink assembly disposed between the first ESC and the second ESC. The first ESC and the second ESC are alternately disposed. The heat sink assembly includes a heat sink main body and a thermally conductive metal and a heat dissipation pipe disposed on the heat sink main body. The thermally conductive metal is in contact with the heat dissipation pipe, and the first ESC and second ESC are in contact with the thermally conductive metal on the heat sink main body respectively, so as to transfer the generated heat to the thermally conductive metal.

In a specific application, in order to facilitate the mounting of the first motor 202 and the second motor 203, the first motor 202 and the second motor 203 in the disclosed embodiments may be respectively disposed at upper and lower parts of the same motor mount 204. Moreover, for the first ESC and the second ESC, in order to ensure the heat dissipation performance of the first ESC and the second ESC, the first ESC and the second ESC may be alternately disposed on the left and right sides of the heat sink assembly. Specifically, an angle of 180° may be formed between the first ESC and the second ESC.

It should be noted that the specific shape and structure, working principle and implementation effect of the ESC assembly in the present embodiment are the same as the specific shape and structure, working principle and implementation effect of the ESC assembly in the above described embodiments corresponding to FIGS. 1 and 2, details of which may refer to the foregoing descriptions and will not be repeated again here.

The power system 2 provided in the disclosed embodiments may effectively reduce the space occupied by the ESC assembly by alternately disposing the first ESC and the second ESC of the ESC assembly. When the first ESC and the second ESC generate a large amount of heat, the heat generated by the first ESC and the second ESC may be effectively dissipated through the heat sink assembly disposed between the first ESC and the second ESC. Specifically, through the thermally conductive metal on the heat sink assembly, most heat generated by the ESCs may be quickly transferred to the heat dissipation pipe. The heat dissipation pipe may quickly dissipate the generated heat, thereby achieving fast and effective heat dissipation for the first ESC and the second ESC. This improves the stability and reliability of the operation of the ESC assembly, facilitates the maintenance of the ESC assembly, ensures the practical applications of the power system 2, and is also beneficial to the market promotions and applications.

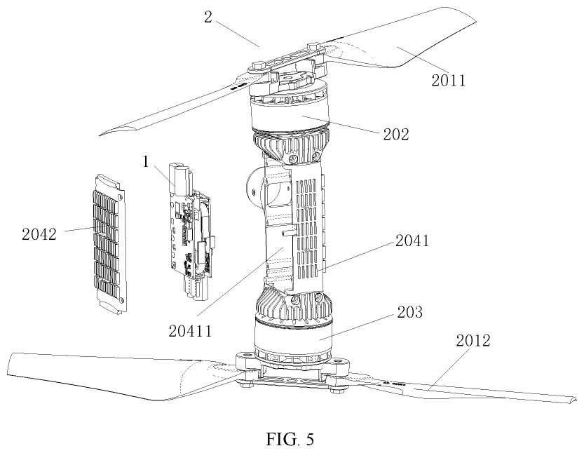

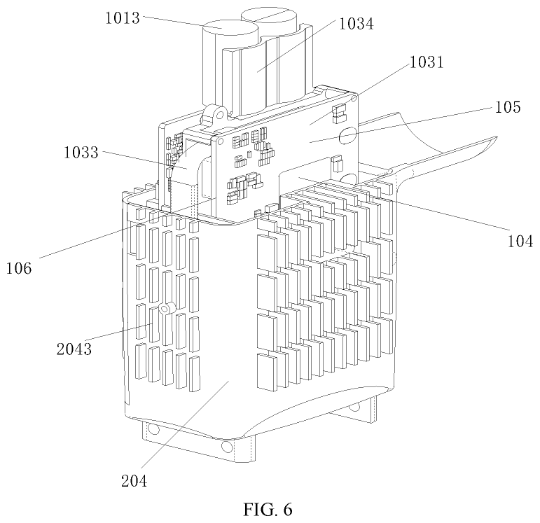

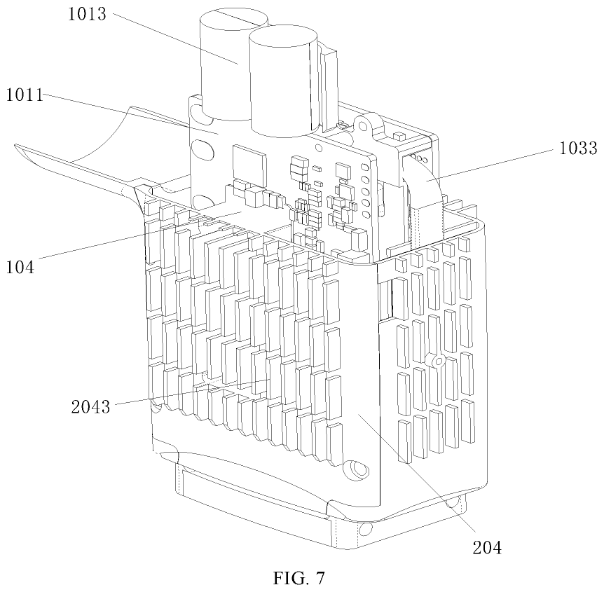

FIG. 5 is a schematic structural diagram of a split power system according to some embodiments of the present disclosure. FIG. 6 is a schematic structural diagram of a part of the power system according to some embodiments of the present disclosure. FIG. 7 is a schematic structural view of a part of the power system according to other embodiments of the present disclosure. In view of the foregoing embodiments, continuing to refer to FIGS. 4-7, the disclosed embodiments do not limit the specific shape and structure of the motor mount 204, and those skilled in the art may set/select/determine according to specific design requirements. For one example, the motor mount 204 may include a mount body 2041 and a mount side plate 2042 connected to the mount body 2041, where the mount side plate 2042 may be detachably connected to the mount body 2041. The mount body 2041 includes a receiving chamber 20411 for holding the ESC assembly disposed thereon.

Here, the specific shape and structure of the receiving chamber 20411 may match the shape and structure of the ESC assembly. For example, when the overall shape and structure of the ESC assembly is a rectangular structure, the receiving chamber 20411 may also be a rectangular chamber. When the overall shape and structure of the ESC assembly is a circular structure, the receiving chamber 20411 may also be a circular chamber. In addition, in order to ensure the quality and heat dissipation performance of the ESC assembly, a plurality of metal fins 2043 may be disposed on the outer surface of the motor mount 204. The metal fins 2043 may be in contact with the ESC assembly and/or the heat dissipation pipe in the ESC assembly, thereby effectively ensuring good heat dissipation performance of the ESC assembly.

When the first motor 202 and the second motor 203 are both mounted on the motor mount 204, and when the ESC assembly is connected to the first motor 202 and the second motor 203, the ESC assembly is disposed inside the motor mount 204 at this moment. Specifically, the ESC assembly may include a first surface 105, a second surface (not shown in the figure), and a third surface 106 and a fourth surface (not shown in the figure) between the first surface 105 and the second surface. The first surface 105 is opposite to the second surface, and the third surface 106 is opposite to the fourth surface. Here, the surface area of the first surface 105 is greater than the surface area of the third surface 106, and the first surface 105 and the second surface of the ESC assembly are respectively in contact with the metal fins 2043 via a thermally conductive silicone. The third surface 106 and the fourth surface of the ESC assembly are respectively in contact with the metal fins 2043 through the heat dissipation pipe. It is to be understood that a person skilled in the art may also set the first surface 105 and the second surface of the ESC assembly to be in contact with the metal fins 2043 through the heat dissipation pipe, while the third surface 106 and the fourth surface are in contact with the metal fins 2043 through a thermally conductive silicone.

Through setting the first surface 105 and the second surface of the ESC assembly to be in direct contact with the metal fins 2043 through the thermally conductive silicone, and through setting the third surface 106 and the fourth surface to be in direct contact with the metal fins 2043 through the heat dissipation pipe, the stability and reliability for the contact between the ESC assembly and the metal fins 2043 can be effectively ensured. Meanwhile, the quality and efficiency of heat dissipation of the ESC assembly by the metal fins 2043 may be improved.

In view of the foregoing embodiments, continuing to refer to FIGS. 4-7, the first ESC and the second ESC in the ESC assembly may be respectively disposed on the left and right sides of the heat sink assembly. The first ESC and the second ESC are respectively connected to the heat dissipation pipe through the thermally conductive metal. Therefore, in order to ensure the heat dissipation performance of the first ESC and the second ESC, the thermally conductive metal in the disclosed embodiments may include a first thermally conductive metal disposed on one side of the heat sink assembly. The first ESC is in contact with the first thermally conductive metal. Specifically, the first ESC may be in contact with the first thermally conductive metal through a thermally conductive silicone.

Further, the thermally conductive metal may also include a second thermally conductive metal disposed on the other side of the heat sink assembly. The second ESC is in contact with the second thermally conductive metal. Specifically, the second ESC is in contact with the second thermally conductive metal through a thermally conductive silicone.

Here, the specific shapes and structures and heat dissipation principle of the first thermally conductive metal and the second thermally conductive metal in the present embodiment are the same as the specific shapes and structures and heat dissipation principle of the first thermally conductive metal and the second thermally conductive metal in the foregoing embodiments corresponding to FIGS. 1 and 2, details of which may refer to the foregoing descriptions and will not be repeated again here.

In the disclosed embodiments, by configuring the thermally conductive metal in the heat sink assembly as the first thermally conductive metal and the second thermally conductive metal, the heat dissipation performance of the heat sink assembly for the first ESC and the second ESC is effectively improved. This further ensures the heat dissipation quality and efficiency of the ESC assembly, while also improving the stability and reliability of the power system 2.

In view of the foregoing embodiments, continuing to refer to FIGS. 4-7, the disclosed embodiments do not limit the number and the shape and structure of the heat dissipation pipes in the heat sink assembly, and those skilled in the art may set/select/determine according to specific design requirements. For example, the number of heat dissipation pipes may be set to at least two. Moreover, the heat dissipation pipes may further include a heat receiving end, a pipe body and a heat dissipating end. The heat receiving end is connected to the heat dissipating end through the pipe body. Accordingly, the heat receiving end is connected to the thermally conductive metal, and the heat dissipating end is connected to the metal fins 2043.

Here, the specific shape and structure and heat dissipation principle of the heat dissipation pipe in the present embodiment are the same as the specific shape and structure and heat dissipation principle of the heat dissipation pipe in the embodiments corresponding to FIGS. 1-3, details of which may refer to the foregoing descriptions and will not be repeated again here.

By setting the number of heat dissipation pipes to be multiple, and by including a heat receiving end and a heat dissipating end on a heat dissipation pipe, the heat generated by the ESCs is transferred to the heat receiving end of the heat dissipation pipe through the thermally conductive metal. After receiving the generated heat, the heat receiving end of the heat dissipation pipe may quickly transfer the heat to the heat dissipating end for heat dissipation. Since the heat dissipating end is also connected with the metal fins 2043, the heat generated by the ESCs may be dissipated even more quickly, thereby improving the heat dissipation performance of the power system 2.

In view of the foregoing embodiments, continuing to refer to FIGS. 4-7, the disclosed embodiments do not limit the specific shape and structure of the first ESC and the second ESC, and those skilled in the art may set/select/determine according to specific design requirements. For example, the first ESC may include a first motherboard and a first main heat irradiating component disposed on the first motherboard, and the first main heat irradiating component is in contact with the first thermally conductive metal through a thermally conductive silicone. Specifically, the first ESC further includes a first capacitor disposed at one end of the first motherboard, and the heat sink main body is provided with a first recess for holding the first capacitor.

Further, the second ESC includes a second motherboard and a second main heat irradiating component disposed on the second motherboard, and the second main heat irradiating component is in contact with the second thermally conductive metal through a thermally conductive silicone. Specifically, the second ESC further includes a second capacitor disposed at one end of the second motherboard. The heat sink main body is provided with a second recess for holding the second capacitor. At this point, the first recess may be disposed at an upper part of the heat sink main body, while the second recess is disposed at a lower part of the heat sink main body.

Here, the specific shape and structure, the heat dissipation principle, and the implementation effect of the first ESC and the second ESC in the current embodiment are the same as the specific shape and structure, the heat dissipation principle, and the implementation effect of the first ESC and the second ESC in the above described embodiments corresponding to FIGS. 1-3, details of which may refer to the foregoing descriptions and will not be repeated again here.

In a specific application, the power system 2 may be a power system 2 for a group of multi-rotor UAVs. In view of the reliability, maintainability and space utilization, the power system 2 may adopt two ESCs (e.g., a first ESC and a second ESC), which drive the upper and lower motors (e.g., the first motor 202 and the second motor 203, respectively).

With respect to the design principle, the ESC assembly of the power system 2 in the disclosed embodiments adopts a two-side heat dissipation design, where the first ESC and the second ESC are disposed in a staggered stacked manner. On the heat transfer path, the heat on one side of each ESC may be transferred to the metal fins 2043 of the motor mount 204 through a thermally conductive silicone, and the heat on the other side may be transferred to the middle heat sink assembly through a thermally conductive silicone. The heat sink assembly includes a thermally conductive metal and a heat dissipation pipe. The heat dissipation pipe is a special structure with a rapid heat transfer capacity, which may quickly transfer the heat received by the thermally conductive metal from the ESCs to the metal fins 2043 of the motor mount 204. Eventually, the strong airflow of the coaxial twin-blade systems may remove the heat on the metal fins 2043. Accordingly, the heat dissipation performance of the power system 2 is effectively ensured, and the stability and reliability of the power system 2 is improved.

In the disclosed embodiments, through the adoption of an ESC assembly (including a first ESC and a second ESC) to respectively drive the first motor 202 and the second motor 203, the maintainability and replaceability of the ESC assembly may be ensured. Through a staggered and stacked manner to dispose two ESCs, space may be saved. Through the adoption of the above heat dissipation design principle, the safety and reliability of the power system 2 may be further improved.

In another aspect, the embodiments of the present disclosure provide a UAV. The UAV may be a multi-rotor UAV. Specifically, the UAV may include:

a central body;

an arm connected to the central body;

a power system disposed at or near an end of the arm, where the power system in the present embodiment may be the power system provided in any of the foregoing embodiments.

Here, the specific shape and structure, working principle and implementation effect of the power system in the present embodiment are the same as the specific shape and structure, working principle and implementation effect of the power system in the above described embodiments corresponding to FIGS. 4-7, details of which will be not repeated again here.

The UAV provided by the disclosed embodiments effectively ensures the safety and reliability of the flight of the UAV by including an above described power system. Specifically, by alternately disposing the first ESC and second ESC of the ESC assembly, the power system may effectively reduce the space occupied by the ESC assembly. In addition, when both the first ESC and the second ESC generate a large amount of heat, through the heat sink assembly disposed between the first ESC and the second ESC, the heat generated by the first ESC and the second ESC may be effectively dissipated. Specifically, most of the heat generated by the ESCs may be quickly transferred to the heat dissipation pipe through the thermally conductive metal on the heat sink assembly, and the heat dissipation pipe may quickly dissipate the generated heat, thereby achieving rapid and effective heat dissipation of the first ESC and the second ESC. This improves the stability and reliability of the ESC assembly, facilitates maintenance of the UAV, ensures the safety and reliability of the UAV flight, and is beneficial to the market promotions and applications of the UAVs.

It should be noted that the foregoing embodiments are merely illustrative of the technical solutions of the present disclosure, and are not intended to be limiting. Although the present disclosure has been described in detail with reference to the foregoing embodiments, those skilled in the art will understand that the technical solutions described in the foregoing embodiments may be modified, or partial or all of the technical features may be equivalently substituted. These modifications or substitutions do not deviate from the technical solutions of the embodiments of the present disclosure.

What is claimed is:

1. An electronic speed controller (ESC) assembly comprising:
a first ESC for driving a first motor;
a second ESC for driving a second motor; and
a heat sink assembly disposed between the first ESC and the second ESC, wherein
the first motor is configured to drive an upper propeller to generate a lift, and the second motor is configured to drive a lower propeller to generate a lift,
the first ESC and the second ESC are alternately disposed,
the heat sink assembly includes a heat sink main body, and a thermally conductive metal and a heat dissipation pipe disposed on the heat sink main body, wherein the thermally conductive metal is connected to the heat dissipation pipe, and the first ESC and the second ESC are respectively in contact with the thermally conductive metal on the heat sink main body to transfer generated heat to the thermally conductive metal.

2. The ESC assembly of claim 1, wherein the first ESC and the second ESC are alternately disposed on opposite sides of the heat sink assembly.

3. The ESC assembly of claim 2, wherein the thermally conductive metal comprises a first thermally conductive metal disposed on a first side of the heat sink assembly, and the first ESC is in contact with the first thermally conductive metal.

4. The ESC assembly of claim 3, wherein the first ESC is in contact with the first thermally conductive metal via a thermally conductive silicone.

5. The ESC assembly of claim 3, wherein the thermally conductive metal further includes a second thermally conductive metal disposed on a second side of the heat sink assembly, and the second ESC is in contact with the second thermally conductive metal.

6. The ESC assembly of claim 5, wherein the second ESC is in contact with the second thermally conductive metal via a thermally conductive silicone.

7. The ESC assembly of claim 1, wherein the number of heat dissipation pipes is at least two.

8. The ESC assembly of claim 7, wherein the heat dissipation pipe comprises a heat receiving end, a pipe body and a heat dissipating end, and the heat receiving end is connected to the heat dissipating end through the pipe body.

9. The ESC assembly of claim 8, wherein the heat receiving end is connected with the thermally conductive metal, and the heat dissipating end is connected with metal fins.

10. The ESC assembly of claim 9, wherein the metal fins are disposed on a motor mount, the motor mount being configured to mount the first motor and the second motor.

11. The ESC assembly of claim 5, wherein the first ESC includes a first motherboard and a first main heat irradiating component disposed on the first motherboard, and the first main heat irradiating component is in contact with the first thermally conductive metal via a thermally conductive silicone.

12. The ESC assembly of claim 11, wherein the first ESC further includes a first capacitor disposed at one end of the first motherboard, and the heat sink main body includes a first recess for holding the first capacitor.

13. The ESC assembly of claim 12, wherein the second ESC includes a second motherboard and a second main heat irradiating component disposed on the second motherboard, and the second main heat irradiating component is in contact with the second thermally conductive metal via the thermally conductive silicone.

14. The ESC assembly of claim 13, wherein the second ESC further includes a second capacitor disposed at another end of the second motherboard, and the heat sink main body includes a second recess for holding the second capacitor.

15. The ESC assembly of claim 14, wherein the first recess is disposed at an upper part of the heat sink main body, and the second recess is disposed at a lower part of the heat sink main body.

16. The ESC assembly of claim 1, wherein the first ESC and the second ESC form an angle of 180°.

17. A power system comprising: a propeller, a first motor, a second motor, and an ESC assembly for driving the first motor and the second motor, the propeller including an upper propeller connected with the first motor and a lower propeller connected with the second motor, wherein the ESC assembly includes:
a first ESC for driving a first motor;
a second ESC for driving a second motor; and
a heat sink assembly disposed between the first ESC and the second ESC, wherein
the first motor is configured to drive the upper propeller to generate a lift, and the second motor is configured to drive the lower propeller to generate a lift,
the first ESC and the second ESC are alternately disposed,
the heat sink assembly includes a heat sink main body, and a thermally conductive metal and a heat dissipation pipe disposed on the heat sink main body, wherein the thermally conductive metal is connected to the heat dissipation pipe, and the first ESC and the second ESC respectively are in contact with the thermally conductive metal on the heat sink main body to transfer generated heat to the thermally conductive metal.

18. The power system of claim 17, wherein the first motor and the second motor are respectively disposed at an upper part and a lower part of the same motor mount.

19. The power system of claim 18, wherein the motor mount includes a mount body and a mount side panel coupled to the mount body, the mount body being configured to include a receiving chamber for holding the ESC assembly.

20. The power system of claim 18, wherein an outer surface of the motor mount is provided with a plurality of metal fins.

21. The power system of claim 18, wherein the ESC assembly includes a first surface, a second surface, and a third surface and a fourth surface between the first surface and the second surface, the first surface is opposite to the second surface, the third surface is opposite to the fourth surface, and a surface area of the first surface is greater than a surface area of the third surface;
the first surface and the second surface of the ESC assembly are respectively in contact with metal fins via a thermally conductive silicone.

22. The power system of claim 21, wherein the third surface and the fourth surface of the ESC assembly are in contact with the metal fins through a heat dissipation pipe, respectively.

23. The power system of claim 17, wherein the first ESC and the second ESC are alternately disposed on the left side and right side of the heat sink assembly.

24. The power system of claim 23, wherein the thermally conductive metal comprises a first thermally conductive metal disposed on one side of the heat sink assembly, and the first ESC is brought into contact with the first thermally conductive metal.

25. The power system of claim 24, wherein the first ESC is contacted with the first thermally conductive metal via a thermally conductive silicone.

26. The power system of claim 24, wherein the thermally conductive metal further comprises a second thermally conductive metal disposed on the other side of the heat sink assembly, and the second ESC is brought into contact with the second thermally conductive metal.

27. The power system of claim 26, wherein the second ESC is in contact with the second thermally conductive metal via a thermally conductive silicone.

28. The power system of claim 20, wherein the number of heat dissipation pipes is at least two.

29. The power system of claim 28, wherein the heat dissipation pipe comprises a heat receiving end, a pipe body and a heat dissipating end, and the heat receiving end is connected to the heat dissipating end through the pipe body.

30. The power system of claim 29, wherein the heat receiving end is in contact with the thermally conductive metal and the heat dissipating end is in contact with the metal fins.

31. The power system of claim 26, wherein the first ESC comprises a first motherboard and a first main heat irradiating component disposed on the first motherboard, and the first main heat irradiating component is in contact with the first thermally conductive metal connects via a thermally conductive silicone.

32. The power system of claim 31, wherein the first ESC further comprises a first capacitor disposed at one end of the first motherboard, and the heat sink main body is provided with a first recess for holding the first capacitor.

33. The power system of claim 32, wherein the second ESC comprises a second motherboard and a second main irradiating component disposed on the second motherboard, the second main heat irradiating component is in contact with the second thermally conductive metal via the thermally conductive silicone.

34. The power system of claim 33, wherein the second ESC further comprises a second capacitor disposed at one end of the second motherboard, and the heat sink main body is provided with a second recess for holding the second capacitor.

35. The power system of claim 34, wherein the first recess is disposed at an upper part of the heat sink main body, and the second recess is disposed at a lower part of the heat sink main body.

36. The power system according to claim 17, wherein an angle of 180 is formed between the first ESC and the second ESC.

37. An unmanned aerial vehicle comprising:
a central body;
an arm connected to the central body; and
a power system disposed at or near one end of the arm, wherein the power system includes a propeller, a first motor, a second motor, and an ESC assembly for driving the first motor and the second motor, the propeller including an upper propeller connected with the first motor and a lower propeller connected with the second motor, wherein the ESC assembly includes:
a first ESC for driving a first motor,
a second ESC for driving a second motor, and
a heat sink assembly disposed between the first ESC and the second ESC, wherein
the first motor is configured to drive the upper propeller to generate a lift, and the second motor is configured to drive the lower propeller to generate a lift,
the first ESC and the second ESC are alternately disposed,
the heat sink assembly includes a heat sink main body, and a thermally conductive metal and a heat dissipation pipe disposed on the heat sink main body, wherein the thermally conductive metal is connected to the heat dissipation pipe, and the first ESC and the second ESC respectively are in contact with the thermally conductive metal on the heat sink main body to transfer generated heat to the thermally conductive metal.
